(19) United States
(12) Patent Application Publication
(10) Pub. No.: US 2024/0203831 A1
(43) Pub. Date: Jun. 20, 2024

(54) SEMICONDUCTOR DEVICE AND METHOD FOR MANUFACTURING THE SAME

(71) Applicant: SAMSUNG ELECTRONICS CO., LTD., SUWON-SI (KR)

(72) Inventors: Anthony Dongick LEE, Suwon-si (KR); Min Chan GWAK, Suwon-si (KR); Guk Hee KIM, Suwon-si (KR); Young Woo KIM, Suwon-si (KR); Jin Kyu KIM, Suwon-si (KR); Sang Cheol NA, Suwon-si (KR); Yun Suk NAM, Suwon-si (KR); Kyoung Woo LEE, Suwon-si (KR); Hidenobu FUKUTOME, Suwon-si (KR)

(21) Appl. No.: 18/486,416

(22) Filed: Oct. 13, 2023

(30) Foreign Application Priority Data
Dec. 14, 2022 (KR) 10-2022-0174852

(51) Int. Cl. H01L 23/48; H01L 21/768; H01L 23/528; H01L 25/18; H10B 80/00

(52) U.S. Cl. CPC H01L 23/481; H01L 21/76898; H01L 23/5286; H01L 25/18; H10B 80/00; H01L 24/13

(57) ABSTRACT

A semiconductor device and a method for manufacturing the same is provided. The semiconductor device includes a power delivery network layer; an insulating layer on the power delivery network layer and having an opening therein; a semiconductor layer filling the opening and covering the insulating layer; a first through-via extending through the semiconductor layer and electrically connected to the power delivery network layer; a second through-via extending through the insulating layer and the semiconductor layer and electrically connected to the power delivery network layer; a logic element on the semiconductor layer and electrically connected to the first through-via; and a passive element on the semiconductor layer and electrically connected to the second through-via.

### CROSS-REFERENCE TO RELATED APPLICATION

This application claims priority from Korean Patent Application No. 10-2022-0174852 filed on Dec. 14, 2022, in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor device and a method for manufacturing the same.

### Description of Related Art

A backside power distribution or delivery network (BSPDN) may provide a transistor, a signal wire and a buried power rail (BPR) on a first surface of a wafer and may provide a power distribution or delivery network (PDN) layer on a second surface of the wafer. The network and the signal wire of the semiconductor device may be disposed on the wafer, while being separated from each other.

### SUMMARY

Embodiments of the present disclosure can provide a semiconductor device with improved product reliability.

Embodiments of the present disclosure may provide a method for manufacturing a semiconductor device to allow a semiconductor package with improved product reliability to be manufactured.

Embodiments, according to the present disclosure, are not limited to the above-mentioned aspects. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

According to an aspect of the present disclosure, there is provided a semiconductor device including a power delivery network layer; an insulating layer on the power delivery network layer and having an opening therein; a semiconductor layer filling the opening and covering the insulating layer; a first through-via extending through the semiconductor layer and electrically connected to the power delivery network layer; a second through-via extending through the insulating layer and the semiconductor layer and electrically connected to the power delivery network layer; a logic element on the semiconductor layer and electrically connected to the first through-via; and a passive element on the semiconductor layer and electrically connected to the second through-via.

According to the aforementioned and other embodiments of the present disclosure, there is provided a semiconductor device including a substrate layer including an insulating layer and a semiconductor layer, wherein the substrate layer includes: a first area including a semiconductor layer; and a second area different from the first area and including a stack of the insulating layer and the semiconductor layer; a logic element and a passive element on a first surface of the substrate layer, wherein the logic element is disposed on the first area of the substrate layer and the passive element is disposed on the second area of the substrate layer; a signal wiring layer on the first surface of the substrate layer and electrically connected to the logic element and the passive element; and a power delivery network layer on a second surface opposite to the first surface of the substrate layer.

According to the aforementioned and other embodiments of the present disclosure, there is provided a method for manufacturing a semiconductor device, the method including forming an insulating layer on a silicon substrate; patterning the insulating layer to form an opening exposing a portion of the silicon substrate; forming a semiconductor layer on the silicon substrate, wherein the semiconductor layer fills the opening and covers at least a portion of the insulating layer, wherein the insulating layer and the semiconductor layer forms a substrate layer.

Specific details of other embodiments are included in detailed descriptions and drawings.

### BRIEF DESCRIPTION OF DRAWINGS

The above and other aspects and features of the present disclosure will become more apparent by describing in detail illustrative embodiments thereof with reference to the attached drawings, in which:

FIG. 1 is a diagram for illustrating a semiconductor device according to some embodiments;

FIG. 2 is an enlarged view of an A area in FIG. 1;

FIG. 3 is a diagram for illustrating a semiconductor package according to some embodiments; and

FIG. 4 to FIG. 12 are diagrams of intermediate structures corresponding to steps for illustrating a method for manufacturing a semiconductor device according to some embodiments.

### DETAILED DESCRIPTIONS

Principles and embodiments of the present invention relate generally to a power distribution or delivery network on opposite sides of a substrate to minimize routing congestion and scale down an area size of the semiconductor device. The backside power delivery network can reduce the area size of the semiconductor device and provide reduced current-resistance (IR) drop, compared to a conventional power delivery network in which the signal wire and the power delivery network layer are disposed on the first surface of the wafer.

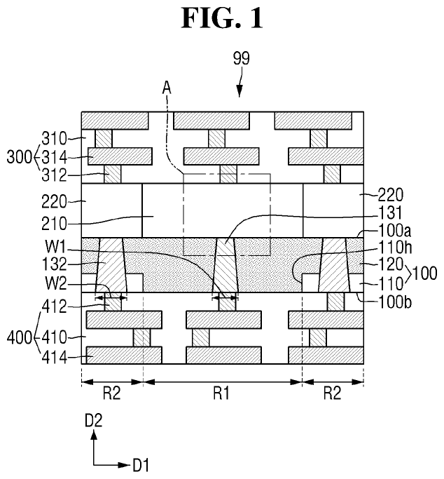

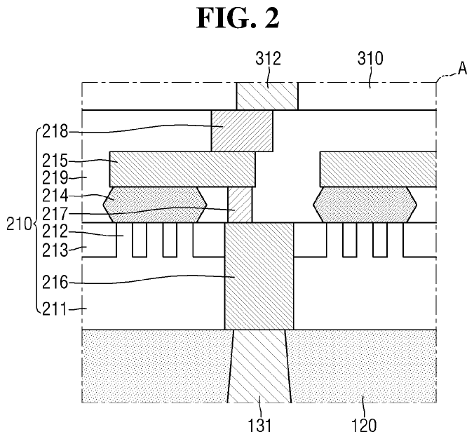

FIG. 1 is a diagram for illustrating a semiconductor device according to some embodiments. FIG. 2 is an enlarged view of an A area in FIG. 1.

Referring to FIGS. 1 and 2, a semiconductor device 99 according to some embodiments may include a substrate layer 100, a logic element 210, a passive element 220, a signal wiring layer 300, and a power delivery network layer 400.

The substrate layer 100 may include a first surface 110a and a second surface 110b opposite to each other in a second direction D2, and separated by a thickness therebetween. In the second direction D2, the first surface 100a may be an upper surface of the substrate layer 100 and the second surface 100b may be a lower surface thereof. The first surface 100a may be referred to as a front surface (or a front side) and the second surface 100b may be referred to as a rear surface (or a back side). The second direction D2 may intersect a first direction D1. The first direction D1 may be a direction parallel to the first surface 100a of substrate layer 100, and the second direction D2 may be a direction perpendicular to the first surface 100a of substrate layer 100. Hereinafter, the upper surface, the lower surface, an upper portion, and a lower portion may be defined based on the second direction D2.

The substrate layer 100 may include an insulating layer 110 and a semiconductor layer 120. The insulating layer 110 may have an opening 110h therein, where the opening 110h can expose an upper surface of the power delivery network layer 400. The semiconductor layer 120 may fill the opening 110h and may cover the insulating layer 110. The semiconductor layer 120 may have a trench extending from the second surface 110b of the substrate layer 100 toward the first surface 110a thereof. The insulating layer 110 may fill the trench. The insulating layer 110 may form a portion of the second surface 100b of the substrate layer 100. A lower surface of the insulating layer 110 and a lower surface of the semiconductor layer 120 may be coplanar with each other, where the lower surface of the insulating layer 110 and a lower surface of the semiconductor layer 120 may form the second surface 100b of the substrate layer 100.

The substrate layer 100 may include a first area R1 and a second area R2 which are different from each other. The first area R1 of the substrate layer 100 may be defined by the opening 110h. The first area R1 may include only the semiconductor layer 120, and the second area R2 may include the insulating layer 110 and the semiconductor layer 120 stacked on top of each other. The first area R1 may be an area in which the insulating layer 110 is not disposed, and the second area R2 may be an area in which the insulating layer 110 is disposed. The first area R1 can be adjoining the second area R2 at the edge of the opening 110h.

For example, the insulating layer 110 may include silicon oxide, and the semiconductor layer 120 may include silicon. The semiconductor layer 120 may be an epitaxially grown silicon layer.

The logic element 210 and the passive element 220 may be disposed on the first surface 100a of the substrate layer 100, where the logic element 210 and the passive element 220 can be in the same layer and laterally adjacent to each other. The logic element 210 may be disposed on the first area R1 of the substrate layer 100, and the passive element 220 may be disposed on the second area R2 of the substrate layer 100. The passive element 220 may overlap the insulating layer 110 in the second direction D2.

The logic element 210 and the passive element 220 may transmit and receive signals such as a data signal and a control signal except for a power voltage and a ground voltage to and from an external device via the signal wiring layer 300, and may receive the power supply voltage or the ground voltage from an external source via the power delivery network layer 400. The power delivery network layer 400 can be on a first side of the logic element 210 and the passive element 220, and the signal wiring layer 300 can be on a second side opposite the first side. The signal wiring layer can be on a side of the logic element 210 and the passive element 220 opposite the first through-via 131 and the second through-via 132.

Referring to FIG. 2, the logic element 210 may include a semiconductor substrate 211, an active pattern 212, an element isolation film 213, a source drain area 214, a contact 215, a buried power rail 216, a power via 217, a contact via 218 and an interlayer insulating film 219. The signal wiring layer 300 can be electrically connected to the contact via 218, and a first through-via 131 can be electrically connected to the buried power rail 216.

The semiconductor substrate 211 may include, for example, a semiconductor material such as Si or Ge, or a compound semiconductor material such as SiGe, SiC, GaAs, InAs, or InP.

The active pattern 212 may protrude, for example, from the semiconductor substrate 211 of the logic element 210 in the second direction D2. The active patterns 212 may be spaced apart from each other. The active pattern 212 may extend, for example, along the first surface 100a of the substrate layer 100. The active pattern 212 may be a portion of the semiconductor substrate 211 and may be defined by a trench formed in the semiconductor substrate 211. The number of active patterns 212 may vary.

In another example, the active pattern 212 may include channel patterns spaced apart from each other and stacked in the second direction D2. The stacked channel patterns may overlap each other in the second direction D2. The channel pattern may include at least one of silicon (Si), germanium (Ge), and silicon-germanium (SiGe).

The element isolation film 213 may be disposed on the semiconductor substrate 211. The element isolation film 213 may be disposed between the active patterns 212, where the element isolation film 213 may separate adjacent pairs of the active pattern 212. The element isolation film 213 may surround at least a portion of a side surface of the active pattern 212. For example, a portion of the active pattern 212 may protrude upwardly beyond the element isolation film 213, where the portion of the active pattern 212 extends above the adjacent surface of the element isolation film 213. The element isolation film 213 may cover a lower portion of the active pattern 212, where the element isolation film 213 can fill a gap between the adjacent pairs of the active pattern 212. An upper portion of the active pattern 212 may not be covered with the element isolation film 213, so as to be exposed.

The element isolation film 213 may include, for example, at least one of silicon oxide, silicon oxynitride, silicon oxycarbonitride, or combinations thereof. However, the present disclosure is not limited thereto.

The source drain area 214 may be disposed on the active pattern 212. The contact 215 may be disposed on the source drain area 214. The contact 215 may physically contact the source drain area 214 and to the power via 217. The contact via 218 may be disposed on the contact 215. The contact via 218 may physically contact the contact 215. The contact via 218 may contact a first via 312. The contact via 218 may be electrically connected to the signal wiring layer 300, and to the source drain area 214.

The buried power rail 216 may be disposed in the semiconductor substrate 211 and the element isolation film 213. At least a portion of the sidewall of the buried power rail 216 may be covered by the element isolation film 213. At least a portion of the buried power rail 216 may be buried in the semiconductor substrate 211. The upper portion of the buried power rail 216 may be surrounded by the element isolation film 213, where the element isolation film 213 can be interposed between the buried power rail 216 and the active pattern 212. The buried power rail 216 may act as a wiring to which a power voltage or a ground voltage is applied. The buried power rail 216 may be in physical contact with a first through-via 131 and the power via 217. The power via 217 may contact the contact 215. An insulating film may be further interposed between the buried power rail 216 and each of the semiconductor substrate 211 and the element isolation film 213.

The buried power rail 216 may include a conductive material, for example, at least one of aluminum (Al), copper (Cu), tungsten (W), molybdenum (Mo), cobalt (Co), ruthenium (Ru), or an alloy thereof. However, the present disclosure is not limited thereto.

The logic element 210 may be, for example, a logic chip including a processor such as a central processing unit (CPU), a graphic processing unit (GPU), an application processor (AP), or a DSP (digital signal processor).

Referring back to FIG. 1, the passive element 220 may include at least one passive element such as a capacitor, a resistor, or an inductor.

The signal wiring layer 300 may be disposed on the first surface 100a of the substrate layer 100, where the logic element 210 and the passive element 220 can be between the signal wiring layer 300 and the substrate layer 100. The signal wiring layer 300 may be electrically connected to the logic element 210 and the passive element 220. The signal wiring layer 300 may include a first interlayer insulating film 310, a first wiring 314, and the first via 312.

The first interlayer insulating film 310 may cover the first surface 100a of the substrate layer 100. The first interlayer insulating film 310 may cover the logic element 210 and the passive element 220. The first interlayer insulating film 310 may include, for example, a stack of a plurality of interlayer insulating films. The first interlayer insulating film 310 may include, for example, at least one of silicon oxide, silicon nitride, or silicon oxynitride. However, the present disclosure is not limited thereto.

The first wiring 314 and the first via 312 may be disposed in the first interlayer insulating film 310. The first wiring 314 may include a plurality of wirings spaced apart from each other in each of the first direction D1 and the second direction D2. The first via 312 may be disposed between first wirings 314 adjacent to each other in the second direction D2. The first via 312 may electrically connect the first wirings 314 adjacent to each other in the second direction D2 to each other. An overlying first via 312 may be laterally offset from an underlying first via 312, where a first wiring 314 can be between and electrically connected to both first vias 312.

Each of the first wiring 314 and the first via 312 may include, for example, at least one of tungsten (W), aluminum (Al), or copper (Cu). However, the present disclosure is not limited thereto.

The first through-vias 131 and second through-vias 132 may be disposed in the substrate layer 100. The first through-via 131 may be disposed in the first area R1, and the second through-via 132 may be disposed in the second area R2. The first through-via 131 may electrically connect the power delivery network layer 400 and the logic element 210 to each other. A buried power rail 216 can be connected to the first through-via 131 and have a portion in the semiconductor substrate 211. The second through-via 132 may electrically connect the power delivery network layer 400 and the passive element 220 to each other. The first and second through-vias 131 and 132 may extend through, for example, the substrate layer 100. The second through-via 132 may extend through the insulating layer 110 and the semiconductor layer 120, while the first through-via 131 may extend through the semiconductor layer 120. An insulating film may be further interposed between each of the first and second through-vias 131 and 132 and the substrate layer 100.

A maximum width W1 in the first direction D1 of the first through-via 131 may be different from a maximum width W2 in the first direction D1 of the second through-via 132. The maximum width W1 in the first direction D1 of the first through-via 131 may be smaller than the maximum width W2 in the first direction D1 of the second through-via 132. The width of each of the first and second through-vias 131 and 132 may, for example, decrease as each of the first and second through-vias 131 and 132 extends toward the first surface 100a of the substrate layer 100, where the first and second through-vias 131 and 132 can have a tapered shape in the D2 direction.

Each of the first and second through-vias 131 and 132 may include a conductive material, for example, at least one of aluminum (Al), copper (Cu), tungsten (W), molybdenum (Mo), cobalt (Co), ruthenium (Ru), or an alloy thereof. The first through-via 131 may include a different material than that of the second through-via 132.

The power delivery network layer 400 may be disposed on the second surface 100b of the substrate layer 100. The power delivery network layer 400 may be electrically connected to the first and second through-vias 131 and 132. The power delivery network layer 400 may include a second interlayer insulating film 410, a second wiring 414, and a second via 412.

The second interlayer insulating film 410 may cover the second surface 100b of the substrate layer 100. The second interlayer insulating film 410 may include, for example, a stack of a plurality of interlayer insulating films. The second interlayer insulating film 410 may include, for example, at least one of silicon oxide, silicon nitride, or silicon oxynitride. However, the present disclosure is not limited thereto.

The second wiring 414 and the second via 412 may be disposed in the second interlayer insulating film 410. The second wiring 414 may include a plurality of wirings spaced apart from each other in each of the first direction D1 and the second direction D2. The second via 412 may be disposed between the second wirings 414 adjacent to each other in the second direction D2. The second via 412 may electrically connect the second wirings 414 adjacent to each other in the second direction D2 to each other. An overlying second via 412 may be laterally offset from an underlying second via 412, where a second wiring 414 can be between and electrically connected to both second vias 412.

The second via 412 disposed at the topmost level in the second direction D2 may contact the first and second through-vias 131 and 132. Each of the second wiring 414 and the second via 412 may transmit the power voltage or the ground voltage. The second wiring 414 and the second via 412 may be electrically connected to the buried power rail 216 via the first and second through-vias 131 and 132.

Each of the second wiring 414 and the second via 412 may include, for example, at least one of tungsten (W), aluminum (Al), or copper (Cu). However, the present disclosure is not limited thereto.

When the signal wiring layer 300 and the power delivery network layer 400 are formed on the first and second surfaces 100a and 100b of the substrate layer 100, respectively, the power delivery network layer 400 may be connected to the buried power rail 216 via the first through-via 131. The first through-via 131 may extend through the substrate layer 100 so as to extend from the power delivery network layer 400 to the buried power rail 216. With the substrate layer 100 having a predefined thickness or smaller, the first through-via 131 can extend through the substrate layer 100.

However, when the passive element 210 and the active element 220 are arranged parallel to the first surface of the substrate layer 100 (for example, in the first direction D1), the thickness of the substrate layer 100 may not be sufficient to completely electrically insulated the logical element 210 from the passive element 220. Accordingly, performance of the semiconductor device may deteriorate.

In the semiconductor device 99 according to some embodiments, the substrate layer 100 may include the insulating layer 110 and the semiconductor layer 120. The logic element 210 may be formed in the first area R1 of the substrate layer 100, and the passive element 220 may be formed in the second area R2 of the substrate layer 100. The passive element 220 may be insulated from the logical element 210 by the interlayer insulating film 219 and element isolation film 213 to prevent performance deterioration of the semiconductor device. Further, the signal wiring layer 300 may be disposed on the first surface 100a of the substrate layer 100 while the power delivery network layer 400 may be disposed on the second surface 100b of the substrate layer 100, thereby reducing an area size of the semiconductor device 99.

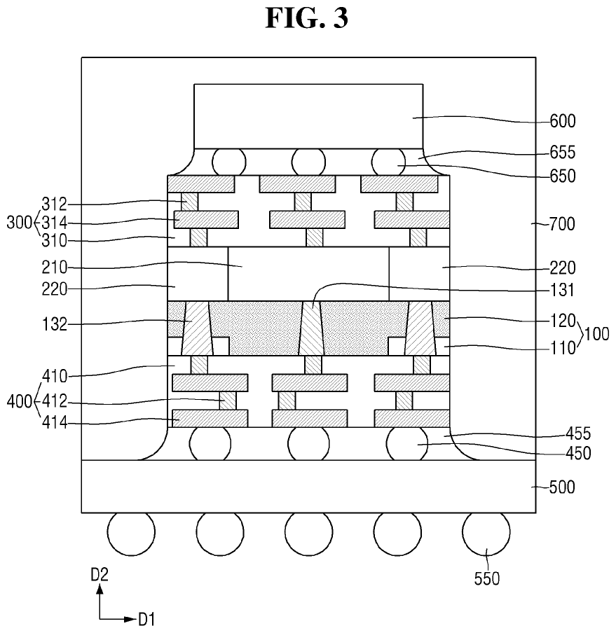

FIG. 3 is a diagram for illustrating a semiconductor package according to some embodiments. For convenience of description, differences thereof from those as described above with reference to FIG. 1 and FIG. 2 are described.

Referring to FIG. 3, the semiconductor package according to some embodiments may include a semiconductor device 99, a first connection terminal 450, a first underfill material layer 455, a package substrate 500, a package connection terminal 550, a semiconductor chip 600, a second connection terminal 650, a second underfill material layer 655, and a molding layer 700. The semiconductor device may be the semiconductor device of FIG. 1.

The semiconductor device may be disposed on the package substrate 500. The first connection terminal 450 may be disposed between the power delivery network layer 400 and the package substrate 500, where there may be a plurality of first connection terminals 450. The first connection terminal 450 may electrically connect the power delivery network layer 400 and the package substrate 500 to each other, where the package substrate 500 can include a plurality of electrical conductors connected to the first connection terminals 450. The first connection terminal 450 may contact the second wiring 414 disposed at the bottommost level in the second direction D2 among the second wirings 414 of the power delivery network layer 400.

The first underfill material layer 455 may fill a space between the semiconductor device and the package substrate 500. The first underfill material layer 455 may surround the first connection terminal 450, where the first underfill material layer 455 can electrically isolate the first connection terminals 450 from each other and from adjacent conductors of the package substrate 500 power delivery network layer 400.

The package substrate 500 may be embodied as, for example, a printed circuit board (PCB), where conductors of the package substrate 500 can electrically connect the first connection terminals 450 with package connection terminals 550. The package connection terminal 550 may be disposed on the package substrate 500, where a plurality of package connection terminals 550 can be on a side of the package substrate 500 opposite the first connection terminals 450. The package connection terminal 550 may be electrically connected to the package substrate 500. The package connection terminal 550 may be embodied as, for example, a solder bump, where the package connection terminals 550 can be electrically connected to the conductors of the package substrate 500. However, the present disclosure is not limited thereto. The package connection terminal 550 may be embodied as various structures such as a land, a ball, a pin, and a pillar.

The semiconductor chip 600 may be disposed on the semiconductor device. The second connection terminal 650 may be disposed between the second semiconductor chip 600 and the signal wiring layer 300, where there can be a plurality of second connection terminals 650. The second connection terminal 650 may electrically connect the second semiconductor chip 600 and the signal wiring layer 300 to each other, where the semiconductor chip 600 can include a plurality of electrical conductors connected to the second connection terminals 650. The second connection terminal 650 may contact the first wiring 314 disposed at the topmost level in the second direction D2 among the first wirings 314 of the signal wiring layer 300, where the second connection terminals 650 can be electrically connected the semiconductor chip 600 to the signal wiring layer 300.

The semiconductor chip 600 may be embodied as a memory semiconductor chip. The memory semiconductor chip may be embodied as, for example, a volatile memory semiconductor chip such as DRAM (Dynamic Random Access Memory) or SRAM (Static Random Access Memory), or a non-volatile memory semiconductor chip such as PRAM (Phase-change Random Access Memory), MRAM (Magnetoresistive Random Access Memory), FeRAM (Ferroelectric Random Access Memory) or RRAM (Resistive Random Access Memory).

Each of the first connection terminals 450 and second connection terminals 650 may include, for example, a solder bump or a solder ball. Each of the first and second connection terminals 450 and 650 may include at least one of, for example, gold (Au), silver (Ag), platinum (Pt), aluminum (Al), or copper (Cu).

The second underfill material layer 655 may fill a space between the semiconductor chip 600 and the semiconductor device. The second underfill material layer 655 may surround the second connection terminal 650, where the second underfill material layer 655 can electrically isolate the second connection terminals 650 from each other and from adjacent conductors of the second connection terminal 650 and signal wiring layer 300.

Each of the first and second underfill material layers 455 and 655 may include an insulating polymer material such as EMC (epoxy molding compound). However, the present disclosure is not limited thereto.

The molding layer 700 may be disposed on the package substrate 500. The molding layer 700 may cover at least a portion of each of the package substrate 500, the semiconductor device 99, and the semiconductor chip 600. The molding layer 700 may surround the semiconductor device and the semiconductor chip 600. The molding layer 700 may include, for example, an epoxy molding compound (EMC), where the molding layer 700 may encapsulate and electrically insulate the semiconductor device 99 and the semiconductor chip 600.

The molding layer 700 may cover, for example, the upper surface of the semiconductor chip 600. In another example, the molding layer 700 may not cover an upper surface of the semiconductor chip 600, where the upper surface of the semiconductor chip 600 may be exposed.

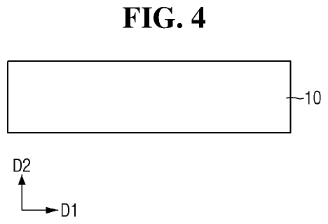

FIG. 4 to FIG. 12 are diagrams of intermediate structures corresponding to intermediate steps for illustrating a method for manufacturing a semiconductor device 99 according to some embodiments.

Referring to FIG. 4, the silicon substrate 10 may be provided.

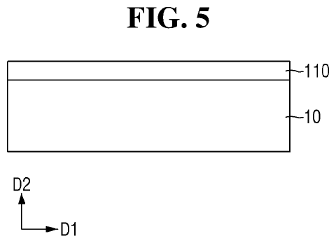

Referring to FIG. 5, the insulating layer 110 may be formed on the silicon substrate 10. The insulating layer 110 may be formed by thermally oxidizing an upper surface of the silicon substrate 10. The insulating layer 110 may be formed using thermal oxidation.

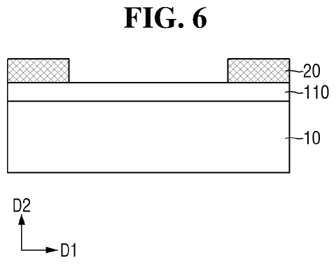

Referring to FIG. 6, a mask pattern 20 may be formed on the insulating layer 110. The mask pattern 20 may expose at least a portion of an upper surface of the insulating layer 110. The mask pattern 20 may expose an upper surface of an area (the first area R1 in FIG. 1) of the silicon substrate 10, where the logic element is to be formed later. The mask pattern 20 may cover an area forming a second area R2 of FIG. 1 of the silicon substrate 10, where the passive element may be formed later.

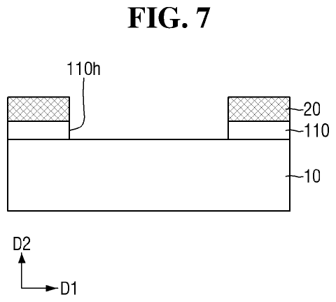

Referring to FIG. 7, a portion of the insulating layer 110 may be removed using the mask pattern 20, where the portion of the insulating layer 110 may be removed by etching to form an opening 110h. Accordingly, the insulating layer 110 may have the opening 110h defined therein exposing a portion of the upper surface of the silicon substrate 10.

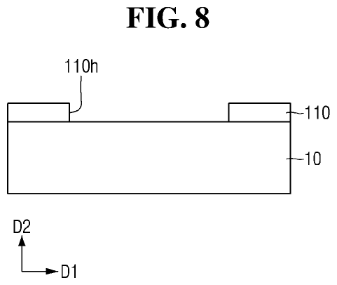

Referring to FIG. 8, the mask pattern 20 may be removed.

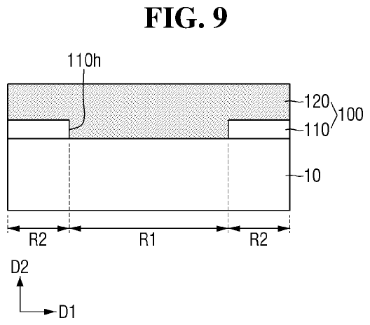

Referring to FIG. 9, the semiconductor layer 120 may be formed on the silicon substrate 10 and the insulating layer 110. The semiconductor layer 120 may fill the opening 110h and cover the insulating layer 110.

The semiconductor layer 120 may be grown from a portion of the silicon substrate 10 exposed through the opening 110h, where the semiconductor layer 120 may be formed via epitaxial growth through the opening 110h. The semiconductor layer 120 may overflow from the opening 110h and extend laterally, so as to cover an upper surface of the insulating layer 110. The semiconductor layer 120 may also be formed on the insulating layer 110 on which silicon does not grow well. Accordingly, the substrate layer 100 including the insulating layer 110 and the semiconductor layer 120 may be formed. The first area R1 of the substrate layer 100 may include the semiconductor layer 120 and the second area R2 of the substrate layer 100 may include the insulating layer 110 and the semiconductor layer 120 stacked in the second direction D2. The first area R1 of the substrate layer 100 may be defined by the opening 110h, where the semiconductor layer 120 may fill the opening 110h.

To form the semiconductor layer 120, an LPCVD (low-pressure chemical vapor deposition) process, a SEG (selective epitaxial growth) process, or a CDE (cyclic deposition and etching) process may be performed using raw materials including an elemental semiconductor precursor. The elemental semiconductor precursor may include a Si source including a Si element. The Si source may include silane (SiH₄), disilane (Si₂H₆), trisilane (Si₃H₈), dichlorosilane (SiH₂Cl₂), etc. However, the present disclosure is not limited thereto.

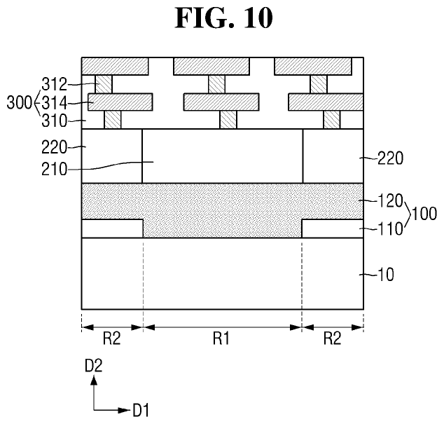

Referring to FIG. 10, the logic element 210 and the passive element 220 may be formed on the substrate layer 100, where the logic element 210 and the passive element 220 may be formed on the semiconductor layer 120 of the substrate layer 100. The logic element 210 may be formed on the first area R1 of the substrate layer 100, and the passive element 220 may be formed on the second area R2 of the substrate layer 100.

The signal wiring layer 300 may be formed on the logic element 210 and the passive element 220. The first via 312, the first wiring 314, and the first interlayer insulating film 310 surrounding the first via 312 and the first wiring 314 may be formed on the logic element 210 and the passive element 220. The signal wiring layer 300 may include a plurality of first vias 312 and a plurality of first wirings 314 stacked in direction D2. The first via 312 may connect first wirings 314 adjacent to each other in the second direction D2 to each other. The first vias 312 disposed at the bottommost level in the second direction D2 may be electrically connected to the logic element 210 in first area R1, and a first vias 312 disposed at the bottommost level in the second area R2 may be electrically connected to the passive element 220. The signal wiring layer 300 may be electrically connected to the logic element 210 and the passive element 220.

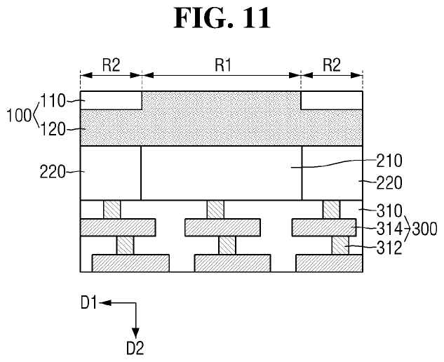

Referring to FIG. 11, a resulting structure of FIG. 10 may be turned upside down in the second direction D2. The silicon substrate 10 may be removed, such that the insulating layer 110 and the semiconductor layer 120 may form a lower surface, and the first wiring 314 and first interlayer insulating film 310 may form an upper surface. Accordingly, the lower surface of the substrate layer 100 in the second direction D2 may be exposed. The lower surface of the insulating layer 110 and the semiconductor layer 120 can have a coplanar surface with removal of the silicon substrate 10.

Subsequently, a thinning process for reducing the thickness of the substrate layer 100 may be performed. The thinning process may include performing grinding or polishing of or performing anisotropic and isotropic etching of the lower surface of the substrate layer 100 in the second direction D2. A portion of the lower surface of the substrate layer 100 exposed via the removal of the silicon substrate 10 may be etched. A portion of each of the lower surface of the insulating layer 110 and the lower surface of the semiconductor layer 120 may be etched, where the lower surface of the insulating layer 110 and the semiconductor layer 120 can have a coplanar surface.

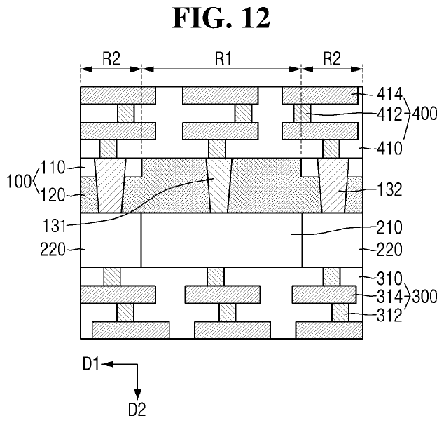

Referring to FIG. 12, the first and second through-vias 131 and 132 may be formed so as to extend through the substrate layer 100. The first through-via 131 may extend through the semiconductor layer 120 of the first area R1, so as to be electrically connected to the logic element 210. The second through-via 132 may extend through the semiconductor layer 120 and the insulating layer 110 of the second area R2, so as to be electrically connected to the passive element 220.

Subsequently, the power delivery network layer 400 may be formed on the substrate layer 100. The power delivery network layer 400 can be formed on the etched surface of the insulating layer 110 and the etched surface of the semiconductor layer 120. On the substrate layer 100, the second via 412, the second wiring 414, and the second interlayer insulating film 410 surrounding the second via 412 and the second wiring 414 may be formed. The second via 412 may connect the second wirings 414 adjacent to each other in the second direction D2 to each other. The second vias 412 disposed at the bottommost level in the second direction D2 may be electrically connected to the first and second through-vias 131 and 132, respectively. Each of the first and second through-vias 131 and 132 may be electrically connected to a stack of second vias 412 and a plurality of second wirings 414. Accordingly, the power delivery network layer 400 may be electrically connected to the logic element 210 and the passive element 220. The power delivery network layer 400 may be electrically connected to the buried power rail (216 of FIG. 2) of the logic element 210.

Next, referring to FIG. 1, a resulting structure of FIG. 12 may be turned upside down in the second direction D2, such that the first wiring 314 and first interlayer insulating film 310 may form an upper surface, and the second wirings 414 and the second interlayer insulating film 410 may form a lower surface. Accordingly, the semiconductor device of FIG. 1 may be manufactured.

Although the embodiments of the present disclosure have been described above with reference to the accompanying drawings, the present disclosure is not limited to the above embodiments, but may be implemented in various different forms. A person skilled in the art will be able to appreciate that the present disclosure may be embodied in other concrete forms without changing the technical spirit or essential characteristics of the present disclosure. Therefore, it should be understood that the embodiments as described above are not restrictive but illustrative in all respects.

What is claimed is:

1. A semiconductor device comprising:
a power delivery network layer;
an insulating layer disposed on the power delivery network layer and having an opening therein;
a semiconductor layer filling the opening and covering the insulating layer;
a first through-via extending through the semiconductor layer and electrically connected to the power delivery network layer;
a second through-via extending through the insulating layer and the semiconductor layer and electrically connected to the power delivery network layer;
a logic element on the semiconductor layer and electrically connected to the first through-via; and
a passive element on the semiconductor layer and electrically connected to the second through-via.

2. The semiconductor device of claim 1, further comprising a signal wiring layer electrically connected to the logic element and the passive element, wherein the signal wiring layer is on a side of the logic element and the passive element opposite the first through-via and the second through-via.

3. The semiconductor device of claim 1, wherein the semiconductor layer includes silicon, and the insulating layer includes silicon oxide.

4. The semiconductor device of claim 1, wherein the logic element includes:
a semiconductor substrate;
an active pattern disposed on the semiconductor substrate;
a power rail connected to the first through-via and having a portion in the semiconductor substrate; and
a contact electrically connecting the power rail and the active pattern to each other.

5. The semiconductor device of claim 1, wherein a lower surface of the insulating layer and a lower surface of the semiconductor layer are coplanar with each other.

6. The semiconductor device of claim 1, wherein the first through-via includes a material different from a material of the second through-via.

7. The semiconductor device of claim 1, wherein a maximum width of the first through-via is different from a maximum width of the second through-via.

8. The semiconductor device of claim 7, wherein the maximum width of the first through-via is smaller than the maximum width of the second through-via.

9. A semiconductor device comprising:
a substrate layer including an insulating layer and a semiconductor layer, wherein the substrate layer includes:
a first area including the semiconductor layer; and
a second area different from the first area and including a stack of the insulating layer and the semiconductor layer;
a logic element and a passive element on a first surface of the substrate layer, wherein the logic element is disposed on the first area of the substrate layer and the passive element is disposed on the second area of the substrate layer;
a signal wiring layer on the first surface of the substrate layer and electrically connected to the logic element and the passive element; and
a power delivery network layer on a second surface of the substrate layer opposite to the first surface.

10. The semiconductor device of claim 9, further comprising:
a first through-via extending through the semiconductor layer of the first area and electrically connected to the power delivery network layer and the logic element; and
a second through-via extending through the stack of the second area and electrically connected to the power delivery network layer and the passive element.

11. The semiconductor device of claim 9, wherein the logic element includes:
a semiconductor substrate;
an active pattern on the semiconductor substrate;
a power rail connected to the first through-via and having a portion in the semiconductor substrate; and
a contact electrically connecting the power rail and the active pattern to each other.

12. A method for manufacturing a semiconductor device, the method comprising:
forming an insulating layer on a silicon substrate;
patterning the insulating layer to form an opening exposing a portion of the silicon substrate; and
forming a semiconductor layer on the silicon substrate, wherein the semiconductor layer fills the opening and covers at least a portion of the insulating layer, wherein the insulating layer and the semiconductor layer forms a substrate layer.

13. The method of claim 12, wherein forming the semiconductor layer includes forming the semiconductor layer via epitaxial growth through the opening.

14. The method of claim 12, wherein forming the insulating layer includes thermally oxidizing an upper surface of the silicon substrate.

15. The method of claim 12, further comprising forming a logic element and a passive element on the substrate layer.

16. The method of claim 15, wherein the substrate layer includes:
a first area including the semiconductor layer; and
a second area different from the first area, and including a stack of the insulating layer and the semiconductor layer,
wherein forming the logic element and the passive element on the substrate layer includes:
forming the logic element on the first area of the substrate layer; and
forming the passive element on the second area of the substrate layer.

17. The method of claim 15, further comprising forming a signal wiring layer on the logic element and the passive element, wherein the signal wiring layer is electrically connected to the logic element and the passive element.

18. The method of claim 12, further comprising:
removing the silicon substrate; and
forming a power delivery network layer on a surface of the substrate layer exposed by the removal of the silicon substrate.

19. The method of claim 18, further comprising:
etching at least a portion of a surface of each of the insulating layer and the semiconductor layer exposed by the removal of the silicon substrate,
wherein the power delivery network layer is formed on the etched surface of the insulating layer and the etched surface of the semiconductor layer.

20. The method of claim 18, wherein the substrate layer includes:
a first area including the semiconductor layer; and
a second area different from the first area, and including a stack of the insulating layer and the semiconductor layer,
wherein the method further comprises:
forming a first through-via extending through the first area of the substrate and electrically connected to the power delivery network layer; and
forming a second through-via extending through the second area of the substrate and electrically connected to the power delivery network layer.
